(19) United States
(12) Patent Application Publication
(10) Pub. No.: US 2014/0054735 A1
(43) Pub. Date: Feb. 27, 2014

(54) PHOTOELECTRIC CONVERSION MODULE

(71) Applicant: SAMSUNG SDI CO., LTD, Yongin-city (KR)

(72) Inventor: Hyun-Chul Kim, Yongin-city (KR)

(73) Assignee: Samsung SDI Co., Ltd., Yongin-city (KR)

(21) Appl. No.: 13/737,362

(22) Filed: Jan. 9, 2013

(30) Foreign Application Priority Data
Aug. 23, 2012 (KR) 10-2012-0092535

(51) Int. Cl. H01L 31/04

(52) U.S. Cl. CPC H01L 31/04
USPC 257/431

(57) ABSTRACT

A photoelectric conversion module is disclosed. In one aspect, the photoelectric conversion module includes 1) first and second conductive substrates facing each other and 2) first and second grid electrodes formed between and respectively electrically connected to the first and second conductive substrates. The photoelectric conversion module also includes a first isolation electrode interposed between and contacting the first conductive substrate and the second grid electrode. The second grid electrode may have a top surface that tightly contacts the first isolation electrode so as to substantially prevent an electrolyte from permeating between the top surface of the second grid electrode and the first isolation electrode.

### RELATED APPLICATIONS

This application claims the benefit of Korean Patent Application No. 10-2012-0092535, filed on Aug. 23, 2012, in the Korean Intellectual Property Office, the disclosure of which is incorporated herein in its entirety by reference.

### BACKGROUND

1. Field

The described technology generally relates to photoelectric conversion modules.

2. Description of the Related Technology

Recently, as an energy source that can replace fossil fuel, various studies have been conducted about a photoelectric conversion module that transforms light energy to electric energy, and solar cells that use solar light draw attention.

Studies have been conducted about solar cells having various driving principles. Among the studies, silicon solar cells or crystalline solar cells having a wafer type that uses a p-n junction of a semiconductor have been widely spread. However, the silicon solar cells or crystalline solar cells require a high manufacturing cost due to their process characteristics, such as the formation of a high purity semiconductor material and handling are not easy.

Unlike a silicon solar cell, a dye-sensitized solar cell mainly includes a photosensitive dye that may generate excited electrons when light having a wavelength of visible light enters, a semiconductor material that may receive the excited electrons, and an electrolyte that reacts with electrons that return form an external circuit. The dye-sensitized solar cell has a very high photoelectric conversion efficiency compared to a conventional solar cell, and thus, is expected to be a next generation solar cell.

### SUMMARY

One inventive aspect is photoelectric conversion modules that have high efficiency of photoelectric conversion rate by reducing a cell gap between conductive substrates facing each other.

Another aspect is a photoelectric conversion module which includes: first and second conductive substrates facing each other; first and second grid electrodes respectively formed on the first and second conductive substrates to form a conductive contact with respect to the first and second conductive substrates; and a first isolation electrode that tightly contacts the first conductive substrate and the second grid electrode between the first conductive substrate and the second grid electrode.

The first isolation electrode may be insulated from the first conductive substrate by interposing an insulating gap therebetween.

The insulating gap may be formed as a line pattern along a surrounding of the second grid electrode.

The insulating gap may be formed through a laser scribing with respect to the first conductive substrate.

The first conductive substrate may include a first substrate and a first conductive film formed on the first substrate, and the first isolation electrode may be formed on the same level as the first conductive film on the first substrate.

The first isolation electrode may include the same components as that of the first conductive film.

The photoelectric conversion module may further include a protective layer formed along a lateral circumference of the second grid electrode.

The protective layer may not be formed on a surface of the second grid electrode that faces the first conductive substrate.

The photoelectric conversion module may further include a second isolation electrode that tightly contacts the second conductive substrate and the first grid electrode between the second conductive substrate and the first grid electrode.

The second isolation electrode may be insulated from the second conductive substrate by interposing an insulating gap therebetween.

The insulating gap may be formed as a line pattern along surroundings of the first grid electrode.

The second conductive substrate may include a second substrate and a second conductive film formed on the second substrate, and the second isolation electrode may be formed on the same level as the second conductive film on the second substrate.

The photoelectric conversion module may further include a light absorption layer disposed between the first and second grid electrodes.

Another aspect is a photoelectric conversion module which includes: first and second conductive substrates facing each other; and first and second grid electrodes respectively formed on the first and second conductive substrates to form a conductive contact with respect to the first and second conductive substrates, wherein the first conductive substrate tightly contacts the second grid electrode.

The first conductive substrate may include a first substrate and a first conductive film formed on the first substrate, and the second grid electrode may tightly contact the first substrate from which the first conductive film is removed.

The photoelectric conversion module may further include a protective layer formed along a lateral circumference of the second grid electrode.

The protective layer may not be formed on a surface of the second grid electrode that faces the first conductive substrate.

The second conductive substrate may tightly contact the first grid electrode.

The second conductive substrate may include a second substrate and a second conductive film formed on the second substrate, and the first grid electrode may tightly contact the second substrate from which the second conductive film is removed.

Another aspect is a photoelectric conversion module comprising: first and second conductive substrates facing each other; first and second grid electrodes formed between and respectively electrically connected to the first and second conductive substrates; and a first isolation electrode interposed between and contacting the first conductive substrate and the second grid electrode.

In the above module, the first conductive substrate comprises a first substrate and a first conductive film formed on the first substrate to be closer to the second conductive substrate than the first substrate. In the above module, the first isolation electrode is electrically insulated from the first conductive film via an insulating gap formed therebetween.

In the above module, the insulating gap is formed as a line pattern along a surrounding of the second grid electrode. In the above module, the first isolation electrode is physically separated from the first conductive film. In the above module, the first isolation electrode is formed on the same level as the first conductive film on the first substrate. In the above module, the first isolation electrode and the first conductive film are formed of the same material.

The above module further comprises a protective layer formed along a lateral circumference of the second grid electrode. In the above module, the protective layer is not formed on a surface of the second grid electrode that faces the first conductive substrate. The above module further comprises an electrolyte provided between the first and second conductive substrates, wherein the second grid electrode has a top surface that tightly contacts the first isolation electrode such that the electrolyte does not permeate or is substantially prevented from permeating between the top surface of the second grid electrode and the first isolation electrode.

The above module further comprises: an electrolyte provided between the first and second conductive substrates; and a second isolation electrode interposed between and contacting the second conductive substrate and the first grid electrode, wherein the first grid electrode has a bottom surface that tightly contacts the second isolation electrode such that the electrolyte does not permeate or is substantially prevented from permeating between the bottom surface of the first grid electrode and the second isolation electrode.

In the above module, the second conductive substrate comprises a second substrate and a second conductive film formed on the second substrate, and wherein the second isolation electrode is formed on the same level as the second conductive film on the second substrate. The above module further comprises a light absorption layer disposed between the first and second grid electrodes.

Another aspect is a photoelectric conversion module comprising: first and second conductive substrates facing each other; and first and second grid electrodes between and respectively electrically connected to the first and second conductive substrates, wherein the first conductive substrate tightly contacts the second grid electrode.

In the above module, the first conductive substrate comprises a first substrate and a first conductive film formed on a first portion of the first substrate to be closer to the second conductive substrate than the first substrate, wherein the first substrate comprises a second portion where the first conductive film is not formed, and wherein the second grid electrode tightly contacts the second portion of the first substrate.

The above module further comprises a protective layer formed along a lateral circumference of the second grid electrode. In the above module, the protective layer is not formed on a surface of the second grid electrode that faces the first conductive substrate. In the above module, the second conductive substrate tightly contacts the first grid electrode.

In the above module, the second conductive substrate comprises a second substrate and a second conductive film formed on a first portion of the second substrate to be closer to the first conductive substrate than the second substrate, wherein the second substrate comprises a second portion where the second conductive film is not formed, and wherein the first grid electrode tightly contacts the second portion of the second substrate.

### BRIEF DESCRIPTION OF THE DRAWINGS

FIG. 1 is an exploded perspective view of a photoelectric conversion module according to an embodiment.

FIG. 2 is an exploded perspective view showing the combination of a first grid electrode and first and second conductive substrates according to an embodiment.

FIG. 3 is an exploded perspective view showing the combination of a second grid electrode and first and second conductive substrates according to an embodiment.

FIG. 4 is a plan view showing the disposition of the first grid electrode and a first isolation electrode.

FIG. 5 is a plan view showing the disposition of the second grid electrode and a second isolation electrode.

FIGS. 6 and 7 are cross-sectional view taken along the line VI-VI of FIG. 1.

FIG. 8 is an exploded perspective view of a photoelectric conversion module according to another embodiment.

FIG. 9 is an exploded perspective view showing a combination of a first grid electrode and first and second conductive substrates according to another embodiment.

FIG. 10 is an exploded perspective view showing a combination of a second grid electrode and first and second conductive substrates according to another embodiment.

FIGS. 11 and 12 are cross-sectional view taken along the line XI-XI of FIG. 8.

### DETAILED DESCRIPTION

Embodiments will now be described with reference to the accompanying drawings.

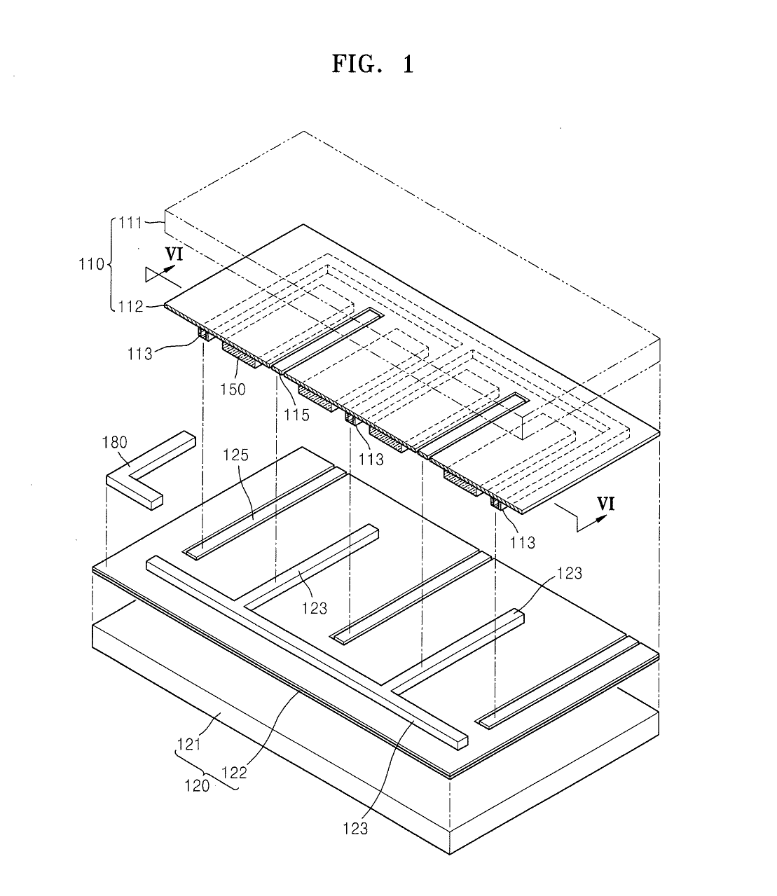

FIG. 1 is an exploded perspective view of a photoelectric conversion module according to an embodiment. Referring to FIG. 1, the photoelectric conversion module includes 1) first and second conductive substrates 110 and 120 which are disposed to face each other and 2) first and second grid electrodes 113 and 123 that are respectively formed on the substrates 110 and 120. The first and second conductive substrates 110 and 120 may include first and second substrates 111 and 121 and first and second conductive films 112 and 122 that are respectively formed on the substrates 111 and 121. A light absorption layer 150 may be disposed between the conductive substrates 110 and 120. Also, a sealing member 180 may be disposed between edges of the two conductive substrates 110 and 120 to seal an electrolyte (not shown) filled in the photoelectric conversion module.

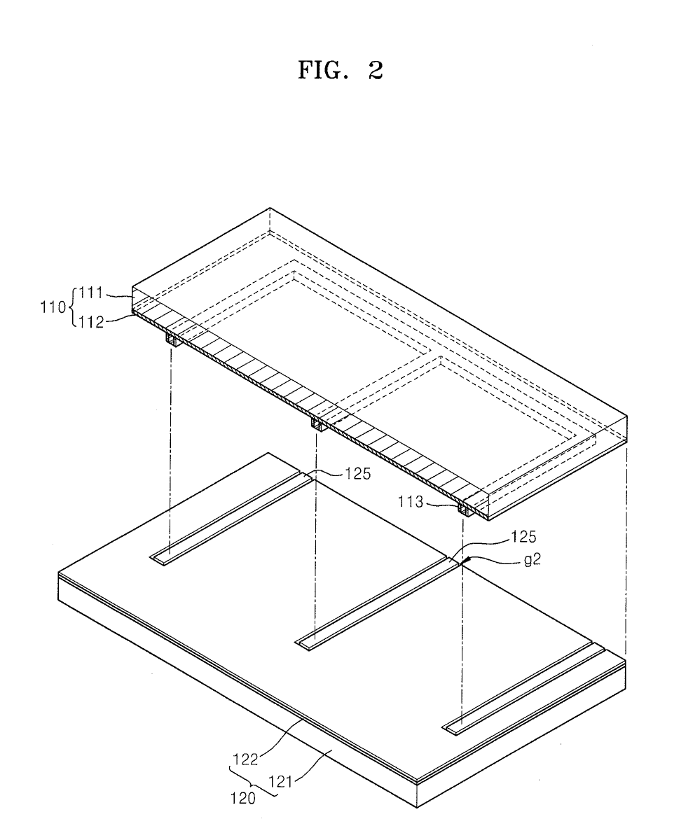

FIG. 2 is an exploded perspective view showing the combination of a first grid electrode 113 and first and second conductive substrates 110 and 120 according to an embodiment. The first grid electrode 113 forms a conductive contact with the conductive substrates 110 and 120 and may be electrically insulated from the second conductive substrates 120. The first grid electrode 113 is formed on the first conductive film 112, may be electrically connected to the first conductive films 112, and may be electrically insulated from the second conductive film 122 through an insulating gap g2 (see FIG. 2).

For example, the insulating gap g2 prevents short circuits between 1) the first grid electrode 113 that functions as a negative electrode of the photoelectric conversion module and 2) the second conductive film 122 that functions as a positive electrode of the photoelectric conversion module. The insulating gap g2 may be formed by a laser scribing to the second conductive substrate 120. That is, the insulating gap g2 may be formed by performing a laser scribing in a line pattern along surroundings of a second isolation electrode 125 that contacts the first grid electrode 113. The second isolation electrode 125 may be formed on the same level as the second conductive film 122 by performing a laser scribing with respect to the second conductive film 122 on the second substrates 121.

For example, the second isolation electrode 125 separated from the second conductive film 122 by a laser scribing may be formed on the same level as the second conductive film 122, and may include substantially the same components included in the second conductive film 122. Accordingly, the second isolation electrode 125 may be formed of the same conductive material used to form the second conductive film 122 and may be insulated from the second conductive film 122 by interposing the insulating gap g2 therebetween.

For example, the first grid electrode 113 may be disposed between and tightly contact the first and second substrates 111 and 121. Also, the first grid electrode 113 may tightly contact the second substrates 121 by interposing the second isolation electrode 125 therebetween.

In this disclosure, “tightly contact” means direct contact or indirect contact. For example, the first grid electrode 113 (or the second grid electrode 123) tightly contacts the first substrate 111 or the second substrate 121 by interposing the first conductive film 112 (or the second conductive film 122) or the second isolation electrode 125 (or a first isolation electrode 115) therebetween.

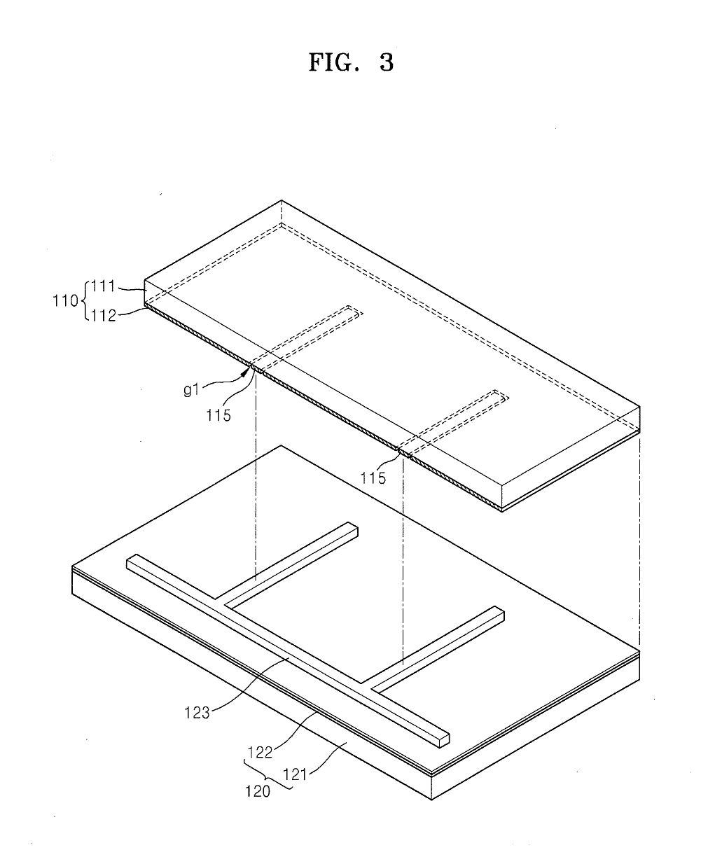

FIG. 3 is an exploded perspective view showing the combination of the second grid electrode 123 and first and second conductive substrates 110 and 120 according to an embodiment. The second grid electrode 123 forms a conductive contact with the second conductive substrate 120 while the second grid electrode 123 may be electrically insulated from the first conductive substrates 110. The second grid electrode 123 is formed on the second conductive film 122 to be electrically connected to the second conductive film 122, and the second grid electrode 123 may be electrically insulated from the first conductive film 112 by an insulating gap g1 (See FIG. 3).

For example, the insulating gap g1 prevents short circuits between second grid electrode 123 that functions as a positive electrode of the photoelectric conversion module and the first conductive film 112 that functions as a negative electrode of the photoelectric conversion module by electrically separating therebetween. The insulating gap g1 may be formed through a laser scribing with respect to the first conductive substrate 110. That is, the insulating gap g1 may be formed by performing a laser scribing in a line pattern along surroundings of a first isolation electrode 115 that contacts the second grid electrode 123. The first isolation electrode 115 may be formed on the same level as the first conductive film 112 by performing a laser scribing with respect to the first conductive film 112 on the first substrate 111.

For example, the first isolation electrode 115 separated from the first conductive film 112 by a laser scribing may be formed on the same level as the first conductive film 112, and may include substantially the same components included in the first conductive film 112. Accordingly, the first isolation electrode 115 may be formed of the same conductive material used to form the first conductive film 112 and may be insulated from the first conductive film 112 by interposing the insulating gap g1 therebetween.

For example, the second grid electrode 123 may be disposed between and tightly contact the first and second substrates 111 and 121. The second grid electrode 123 may tightly contact the second substrate 121 through the second conductive film 122. Also, the second grid electrode 123 may tightly contact the first substrate 111 by interposing the first isolation electrode 115 therebetween.

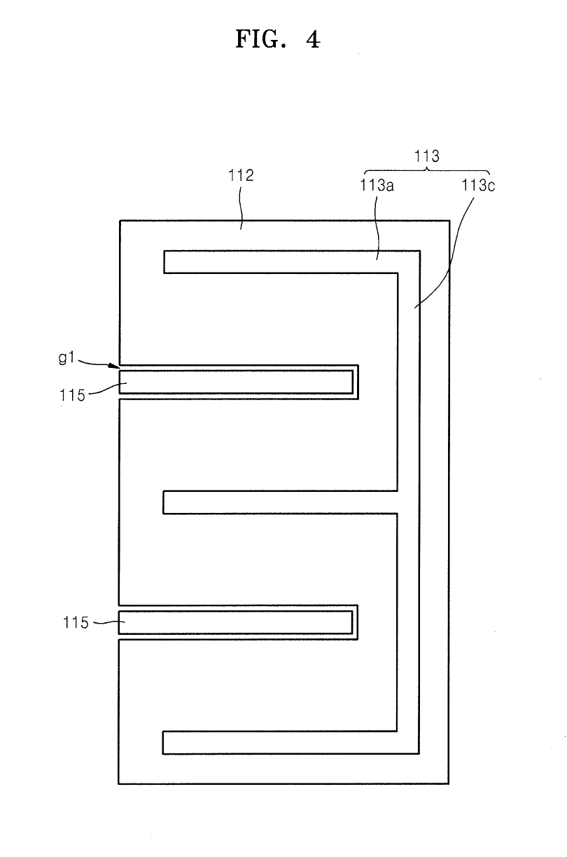

FIG. 4 is a plan view showing the disposition of the first grid electrode 113 and the first isolated electrode 115. Referring to FIG. 4, the first grid electrode 113 may include a plurality of first finger electrodes 113a that extend in substantially parallel to each other in a stripe pattern along a direction and a first current collecting electrode 113c that extends in a direction crossing the first finger electrodes 113a. For example, the first grid electrode 113 may be formed in a generally comb shape as a whole. Electrons collected in the first finger electrodes 113a may be supplied to an external circuit through the first current collecting electrode 113c.

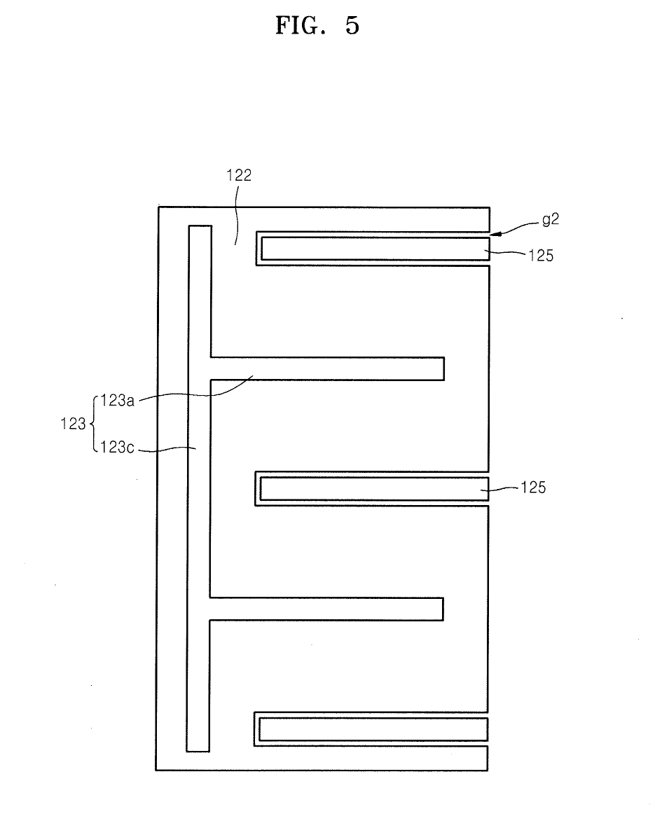

FIG. 5 is a plan view showing the disposition of the second grid electrode 123 and the second isolated electrode 125. Referring to FIG. 5, the second grid electrode 123 may include a plurality of second finger electrodes 123a that extend in substantially parallel to each other in a stripe pattern along a direction and a second current collecting electrode 123c that extends in a direction crossing the second finger electrodes 123a. For example, the second grid electrode 123 may be formed in a generally comb shape as a whole. Electrons supplied through the second finger electrodes 123a may be distributed to every elements of the photoelectric conversion module through the second current collecting electrode 123c.

Referring to FIGS. 4 and 5, the first and second finger electrodes 113a and 123a may extend in substantially parallel to each other in a direction, and may be formed in a pattern in which the first finger electrodes 113a are engaged by being inserted between the second finger electrodes 123a. Also, as depicted in FIG. 4, the first isolation electrode 115 may be disposed on positions where the first isolation electrode 115 contacts the second grid electrode 123 (the second finger electrodes 123a) between the first grid electrode 113 (the first finger electrodes 113a). Similarly, as depicted in FIG. 5, the second isolation electrode 125 may be disposed on positions where the second isolation electrode 125 contacts the first grid electrode 113 (the first finger electrodes 113a) between the second grid electrode 123 (second finger electrodes 123a).

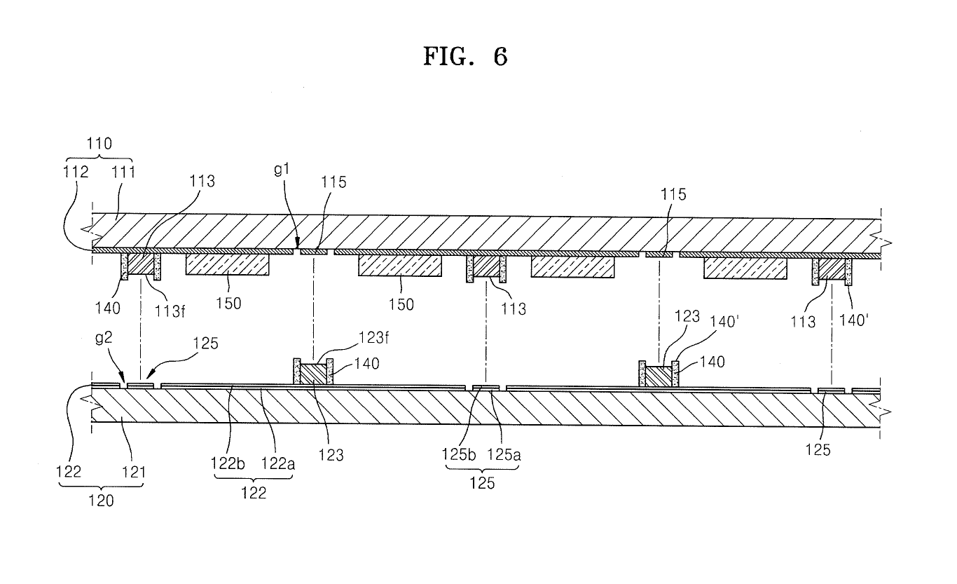

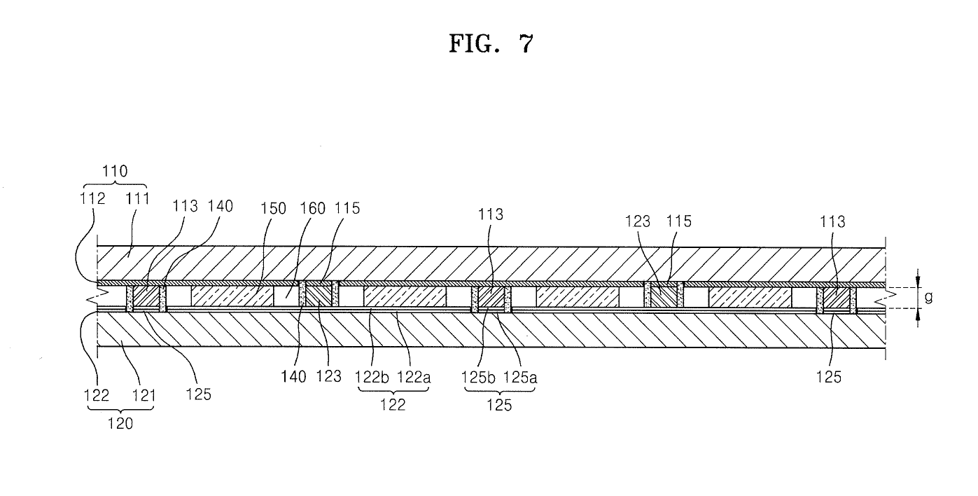

FIGS. 6 and 7 are cross-sectional views taken along the line VI-VI of FIG. 1. Referring to FIGS. 6 and 7, a protective layer 140 may be formed around the first and second grid electrodes 113 and 123. The protective layer 140 separates the first and second grid electrodes 113 and 123 from an electrolyte 160 (refer to FIG. 7), and thus, may prevent the first and second grid electrodes 113 and 123 from corrosion in contacting with the electrolyte 160. The protective layer 140 may be formed along circumferences of the first and second grid electrodes 113 and 123, but may not be formed on a lower surface 113f of the first grid electrode 113 that faces the second substrate 121 and an upper surface 123f of the second grid electrode 123 that faces the first substrate 111. When the protective layer 140 is formed on the lower surface 113f of the first grid electrode 113 and the upper surface 123f of the second grid electrode 123, the thickness of a cell gap g (refer to FIG. 7) increases as much as the thickness of the protective layer 140, and thus, the ion mobility of the electrolyte 160 is reduced as much as a side of the increased cell gap g and the moving distance of a carrier (electrons) is increased. As a result, the current pass resistance is increased, thereby reducing the efficiency of photoelectric conversion.

For example, as a comparative structure in which the protective layer 140 is formed to surround all of the first and second grid electrodes 113 and 123, when the grid electrodes 113 and 123 having a height of about 10 μm are needed, the protective layer 140 is formed to tightly cover the electrodes 113 and 123 by forming the protective layer 140 having a height of approximately in a range from about 40 μm to about 50 μm despite of a step coverage or a process error of the protective layer 140. At this point, due to the protective layer 140 formed to have a relatively high thickness, the cell gap g between the conductive substrates 110 and 120 is increased, and thus, the efficiency of the photoelectric conversion is reduced.

In the current embodiment, the first and second grid electrodes 113 and 123 are interposed between and tightly contact the first and second conductive substrates 110 and 120. Therefore, the lower surface 113f of the first grid electrode 113 and the upper surface 123f of the second grid electrode 123 may be sealed and the approach of the electrolyte 160 to the first and second grid electrodes 113 and 123 may be prevented without the additional protective layer 140. In one embodiment, as shown in FIGS. 6 and 7, the top surface of the second grid electrode 123 tightly contacts the first isolation electrode 115 such that the electrolyte 160 does not permeate or is substantially prevented from permeating between the top surface of the second grid electrode 123 and the first isolation electrode 115. In another embodiment, as shown in FIGS. 6 and 7, the bottom surface of the first grid electrode 113 tightly contacts the second isolation electrode 125 such that the electrolyte 160 does not permeate or is substantially prevented from permeating between the bottom surface of the first grid electrode 113 and the second isolation electrode 125.

For example, the first grid electrode 113 may tightly contact the first substrate 111 through the first conductive film 112, and may tightly contact with respect to the second substrate 121 by interposing the second isolation electrode 125 therebetween. For example, the first grid electrode 113 formed on the first conductive film 112 by using a thin film process (ex. deposition) may tightly contact the second substrate 121 by interposing the second isolation electrode 125 therebetween in a process of sealing the first and second substrates 111 and 121. Accordingly, the lower surface 113f of the first grid electrode 113 that faces the second substrate 121 is not exposed, and may be sealed from the electrolyte 160.

The second grid electrode 123 may tightly contact the second substrate 121 through the second conductive film 122, and may tightly contact with respect to the first substrate 111 by interposing the first isolation electrode 115 therebetween. For example, the second grid electrode 123 formed on the second conductive film 122 by using a thin film process may tightly contact the first substrate 111 by interposing the first isolation electrode 115 therebetween in a process of sealing the first and second substrates 111 and 121. Accordingly, the upper surface 123f of the second grid electrode 123 that faces the first substrate 111 may not be exposed to the electrolyte 160 but may be sealed from the electrolyte 160.

As described above, it is sufficient to form the protective layer 140 along circumferences of the first and second grid electrodes 113 and 123, and although the protective layer 140 is not formed on the lower surface 113f of the first grid electrode 113 and the upper surface 123f of the second grid electrode 123, the contact between the electrodes 113 and 123 and the electrolyte 160 may be prevented. For example, the protective layer 140 may be formed of a resin material that does not react with the electrolyte 160. In the current embodiment, as depicted in FIG. 6, the protective layer 140 may extend downwards of the first and second grid electrodes 113 and 123, and edge units 140′ of the protective layer 140 extended downwards of the grid electrodes 113 and 123 may fill the insulating gaps g1 and g2, and the exposure of the conductive films 112 and 122 through the insulating gaps g1 and g2 may be prevented.

The first and second substrates 111 and 121 may be formed of a glass material of a resin film. The first substrate 111 may be a light receiving surface side, and the second substrate 121 may a non-light receiving surface side.

The first conductive film 112 formed on the first substrate 111 may function as a negative electrode of the photoelectric conversion module. More specifically, the first conductive film 112 may provide a current pass by collecting electrons generated according to the photoelectric conversion action. That is, incident light that enters through the first conductive film 112 may be absorbed in the light absorption layer 150, and electrons generated in the light absorption layer 150 may be delivered to an external circuit through the first conductive film 112 that is conductively connected to the light absorption layer 150.

The first conductive film 112 may be formed of a transparent and conductive oxide (TCO), for example, one selected from the group consisting of indium tin oxide (ITO), fluorine doped tin oxide (FTO), and antimony doped tin oxide (ATO).

The first grid electrode 113 on the first conductive film 112 may provide a low resistance current pass by compensating for electrical conductivity characteristics of the first conductive film 112, and may form a negative electrode side of the photoelectric conversion module together with the first conductive film 112. For example, the first grid electrode 113 may function as a wiring function that provides a current pass of electrons that are collected through the first conductive film 112. The first grid electrode 113 may be formed of a metal having a high electrical conductivity, such as Ag, Au, or Al. Also, the first grid electrode 113 may be formed as a pattern such as a stripe pattern or a mesh pattern.

Incident light that passes through the first conductive film 112 may be absorbed in the light absorption layer 150. The light absorption layer 150 may be electrically connected to the first conductive film 112. For example, the light absorption layer 150 may be formed on the first conductive film 112 to form a conductive contact with the first conductive film 112.

The light absorption layer 150 may include a semiconductor layer and a photosensitive dye adsorbed in the semiconductor layer to increase the efficiency of photoelectric conversion. For example, the semiconductor layer may be formed of a metal oxide selected from the group consisting of Cd, Zn, In, Pb, Mo, W, Sb, Ti, Ag, Mn, Sn, Zr, Sr, Ga, Si, and Cr.

For example, the photosensitive dye may be composed of molecules that are absorbed in a visible light band and may cause rapid electron movement from an optical excited state to the semiconductor layer. For example, the photosensitive dye may be a ruthenium group photosensitive dye.

The light absorption layer 150 may be disposed between the first and second grid electrodes 113 and 123. The first and second grid electrodes 113 and 123 may be alternately arranged, and the light absorption layer 150 may be interposed between the electrodes 113 and 123. In FIG. 7, it is shown the case that the light absorption layer 150 contacts the first and second conductive films 112 and 122. However, the light absorption layer 150 may form a conductive contact with the first conductive film 112, but may be separated from the second conductive film 122.

The electrolyte 160 may be filled between the first and second substrates 111 and 121. The electrolyte 160 may be a redox electrolyte that includes a pair of oxidizing agent and a reducing agent, and may be a solid type electrolyte, a gel type electrolyte, or a liquid type electrolyte.

The second conductive film 122 formed on the second substrate 121 functions as a positive electrode of the photoelectric conversion module, and may function as a reducing catalyst that provides electrons to the electrolyte 160. For example, the light absorption layer 150 excited by absorbing light generates electrons that form an optical current, and the light absorption layer 150 that loses the electrons is re-reduced by obtaining electrons provided by oxidation of the electrolyte 160. The oxidized electrolyte 160 may be re-reduced by electrons transmitted from an external circuit through the second grid electrode 123 and the second conductive film 122.

The second conductive film 122 may include a transparent conductive film 122a and a catalyst layer 122b. The transparent conductive film 122a may be formed of a transparent and conductive oxide (TCO), for example, one selected from the group consisting of indium tin oxide (ITO), fluorine doped tin oxide (FTO), and antimony doped tin oxide (ATO).

The catalyst layer 122b may be formed of a material that functions as a reducing catalyst that may provide electrons to the electrolyte 160. For example, the catalyst layer 122b may be formed of a metal selected from the group consisting of Pt, Ag, Au, and Cu, a metal oxide such as tin oxide, or a carbon group material such as graphite.

In the current embodiment, the second conductive film 122 includes the transparent conductive film 122a and the catalyst layer 122b, but according to another embodiment, the second conductive film 122 may include one of the transparent conductive film 122a and the catalyst layer 122b. Also, the second isolation electrode 125 separated from the second conductive film 122 by interposing the insulating gap g2 therebetween may include a transparent conductive film 125a and a catalyst layer 125b. However, according to another embodiment, the second isolation electrode 125 may include one of the transparent conductive film 125a and the catalyst layer 125b.

When it is said that the second grid electrode 123 is formed on the second conductive film 122, it includes all the cases that the second grid electrode 123 is formed on the transparent conductive film 122a and the catalyst layer 122b which are stacked up and down, is formed only on the transparent conductive film 122a, or is formed only on the catalyst layer 122b.

Also, when it is said that the first grid electrode 113 tightly contacts the second isolation electrode 125, it includes all the cases that the first grid electrode 113 tightly contacts the transparent conductive film 125a and the catalyst layer 125b which are stacked up and down, tightly contacts only the transparent conductive film 125a, or tightly contacts only the catalyst layer 125b.

The second grid electrode 123 on the second conductive film 122 may provide a low resistance current pass by compensating for electrical characteristics of the second conductive film 122, and may form a positive electrode side of the photoelectric conversion module together with the second conductive film 122. For example, the second grid electrode 123 may function as a wiring that performs as a current pass for distributing electrons to the second conductive film 122. The second grid electrode 123 may be formed of a metal having a high electrical conductivity characteristic, such as Ag, Au, or Al. Also, the second grid electrode 123 may be formed as a pattern such as a stripe pattern or a mesh pattern.

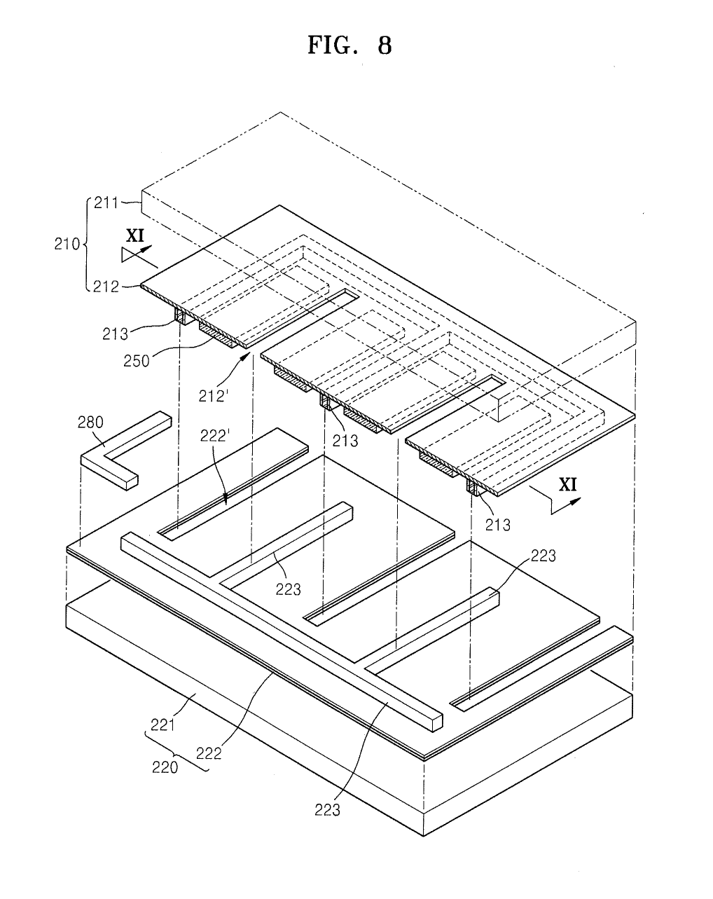

FIG. 8 is an exploded perspective view of a photoelectric conversion module according to another embodiment. Referring to FIG. 8, the photoelectric conversion module includes first and second conductive substrates 210 and 220 and first and second grid electrodes 213 and 223 that are formed respectively on the conductive substrates 210 and 220 to form a conductive contact with the substrates 210 and 220. The first and second conductive substrates 210 and 220 respectively include first and second substrates 211 and 221 and first and second conductive films 212 and 222 formed on the substrates 211 and 221. A light absorption layer 250 may be interposed between the conductive substrates 210 and 220. A sealing member 280 may be disposed between edges of the conductive substrates 210 and 220 to seal an electrolyte (not shown) filled in the photoelectric conversion module.

The first and second grid electrodes 213 and 223 may be formed between and tightly contact the first and second conductive substrates 210 and 220. However, as described below, the first grid electrode 213 may be electrically connected to the first conductive substrate 210, but may be electrically insulated from the second conductive substrate 220 through an insulating gap 222′. Similarly, the second grid electrode 223 may be electrically connected to the second conductive substrate 220, but may be electrically insulated from the first conductive substrate 210 through an insulating gap 212′.

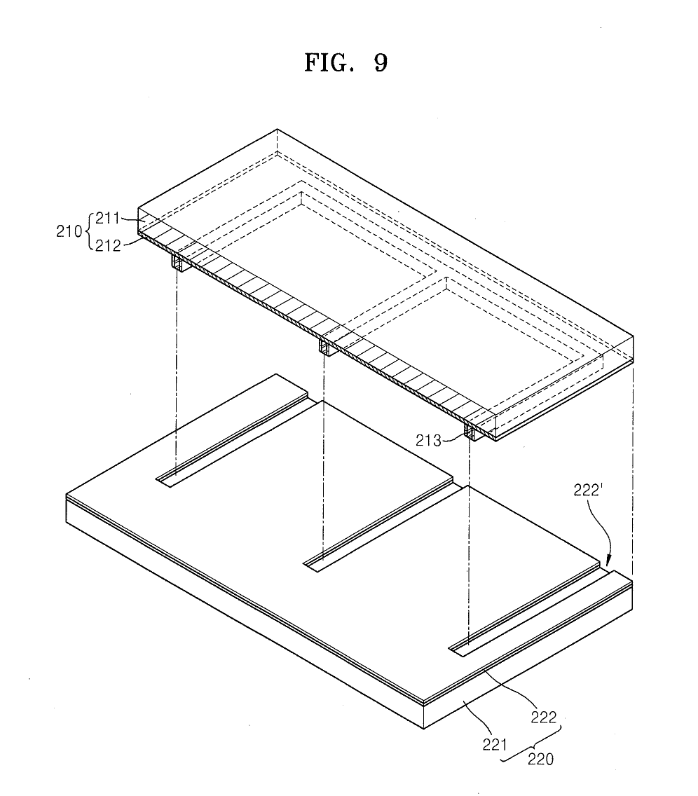

FIG. 9 is an exploded perspective view showing a combination of the first grid electrode 213 and first and second conductive substrates 210 and 220 according to another embodiment. The first grid electrode 213 may form a conductive contact with the first conductive substrate 210, but may be electrically insulated from the second conductive substrate 220. The first grid electrode 213 may be formed on and electrically connected to the first conductive film 212, but may be electrically insulated from the second conductive film 222 through the insulating gap 222′. That is, the first grid electrode 213 may contact the second substrate 221 through the insulating gap 222′ from which the second conductive film 222 is removed. Accordingly, the first grid electrode 213 may be electrically insulated from the second conductive substrate 220.

For example, the insulating gap 222′ prevents internal short circuits between the first grid electrode 213 that functions as a negative electrode of the photoelectric conversion module and the second conductive film 222 that functions as a positive electrode of the photoelectric conversion module by electrically separating the first grid electrode 213 from the second conductive film 222. In the current embodiment, the insulating gap 222′ may be formed by removing the entire portion of the second conductive film 222 that contacts the first grid electrode 213. That is, the insulating gap 222′ may be formed by performing a laser scribing with respect to the entire portion of the second conductive film 222 that contacts the first grid electrode 213.

The first grid electrode 213 may be interposed between and tightly contact the first and second substrates 211 and 221. That is, the first grid electrode 213 may tightly contact the first substrate 211 through the first conductive film 212. In particular, in the current embodiment, the first grid electrode 213 may directly tightly contact with respect to the second substrate 221 through the insulating gap 222′.

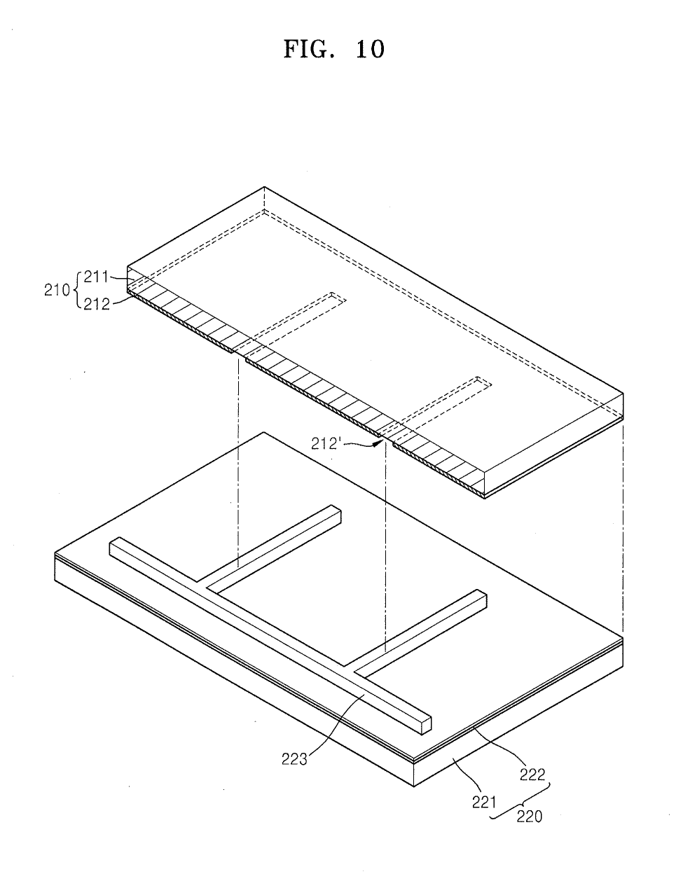

FIG. 10 is an exploded perspective view showing a combination of a second grid electrode 223 and the first and second conductive substrates 210 and 220 according to another embodiment. The second grid electrode 223 may form a conductive contact with the second conductive substrate 220, but may be electrically insulated from the first conductive substrate 210. The second grid electrode 223 is formed on and electrically connected to the second conductive film 222, but may be electrically insulated from the first conductive film 212 through the insulating gap 212′. That is, the second grid electrode 223 may contact the first substrate 211 through the insulating gap 212′ from which the first conductive film 212 is removed. Accordingly, the second grid electrode 223 may be electrically insulated from the first conductive substrate 210.

For example, the insulating gap 212′ prevents internal short circuits between the second grid electrode 223 that functions as a positive electrode of the photoelectric conversion module and the first conductive film 212 that functions as a negative electrode of the photoelectric conversion module by electrically separating the second grid electrode 223 from the first conductive film 212. In the current embodiment, the insulating gap 212′ may be formed by removing the entire portion of the first conductive film 212 that contacts the second grid electrode 223. That is, the insulating gap 212′ may be formed by performing a laser scribing with respect to the entire portion of the first conductive film 212 that contacts the second grid electrode 223.

The second grid electrode 223 may be interposed between and tightly contact the first and second substrates 211 and 221. That is, the second grid electrode 223 may tightly contact the second substrate 221 through the second conductive film 222. In particular, in the current embodiment, the second grid electrode 223 may directly tightly contact the first substrate 211 through the insulating gap 212′.

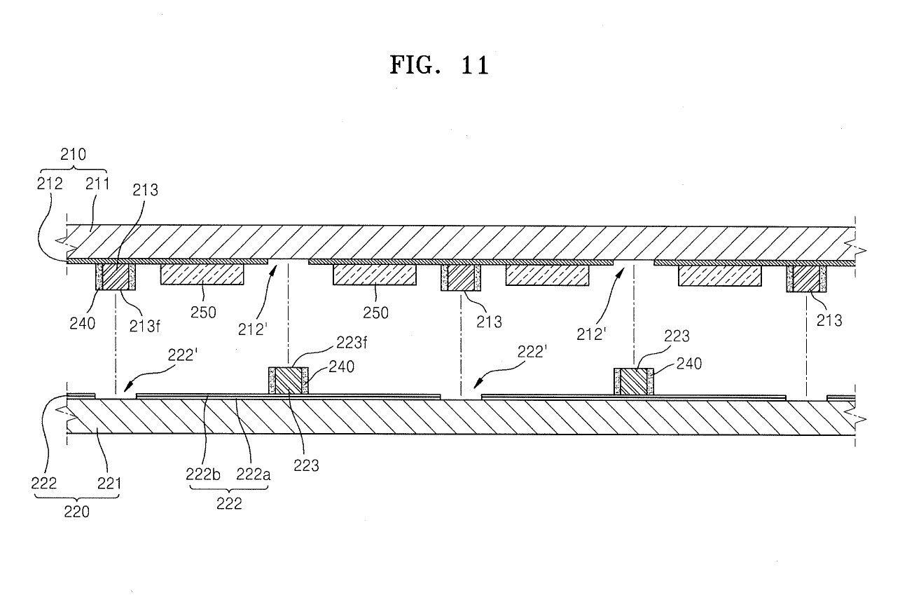

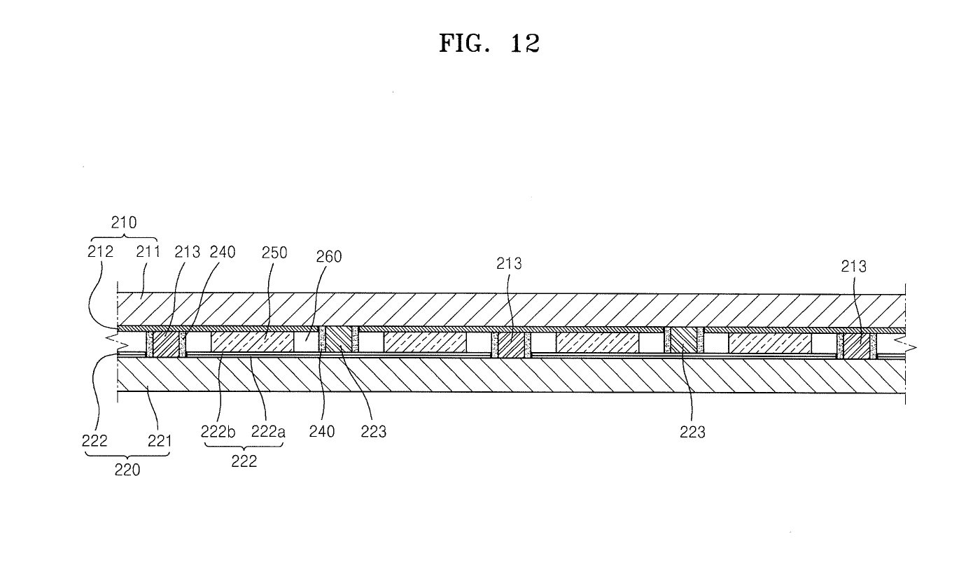

FIGS. 11 and 12 are cross-sectional views taken along the line XI-XI of FIG. 8. Referring to FIGS. 11 and 12, a protective layer 240 may be formed around the first and second grid electrodes 213 and 223. The protective layer 240 separates the first and second grid electrodes 113 and 123 from an electrolyte 160 (refer to FIG. 7), and thus, may prevent the grid electrodes 113 and 123 from corrosion in contacting with the electrolyte 160. The protective layer 240 may be formed along circumferences of the electrodes 213 and 223, but may not be formed on a lower surface 213f of the first grid electrode 213 that faces the second substrate 221 and an upper surface 123f of the second grid electrode 223 that faces the first substrate 211. In the current embodiment, since the grid electrodes 213 and 223 are formed between and tightly contact the first and second substrates 211 and 221, the lower surface 213f of the first grid electrode 213 that faces the second substrate 221 and the upper surface 223f of the second grid electrode 223 that faces the first substrate 211 may be sealed not to be exposed. Therefore, although the protective layer 240 is not formed on the lower surface 213f and the upper surface 223f, the approach of an electrolyte 260 (refer to FIG. 12) to the first and second grid electrodes 213 and 223 may be prevented. In one embodiment, as shown in FIGS. 11 and 12, the top surface of the second grid electrode 223 tightly contacts an exposed portion of the first substrate 211 (where the first conductive film 212 is not formed) such that the electrolyte 260 does not permeate or is substantially prevented from permeating between the top surface of the second grid electrode 223 and the exposed portion of the first substrate 211. In another embodiment, as shown in FIGS. 11 and 12, the bottom surface of the first grid electrode 213 tightly contacts an exposed portion of the second substrate 221 (where the second conductive film 222 is not formed) such that the electrolyte 260 does not permeate or is substantially prevented from permeating between the bottom surface of the first grid electrode 213 and the exposed portion of the second substrate 221.

For example, the first grid electrode 213 may indirectly tightly contact the first substrate 211 through the first conductive film 212, and may directly tightly contact the second substrate 221 through the insulating gap 222′. The first grid electrode 213 formed on the first conductive film 112 through a thin film process may directly tightly contact the second substrate 221 through the insulating gap 222′ in a process of sealing the first and second substrates 211 and 221. Accordingly, the lower surface 213f of the first grid electrode 213 may be sealed from the electrolyte 260.

For example, the second grid electrode 223 may indirectly tightly contact the second substrate 221 through the second conductive film 222, and may directly tightly contact the first substrate 211 through the insulating gap 212′. For example, the second grid electrode 223 formed on the second conductive film 222 by using a thin film process may directly tightly contact the first substrate 211 through the insulating gap 121′ in a process of sealing the first and second substrates 211 and 221. Accordingly, the upper surface 223f of the second grid electrode 223 that faces the first substrate 211 may not be exposed to the electrolyte 260 but may be sealed from the electrolyte 260.

Incident light that passes through the first conductive film 212 may be absorbed in a light absorption layer 250. The light absorption layer 250 may be excited by absorbing light, and excited electrons are delivered to the outside to form a current. The light absorption layer 250 that loses the electrons is re-reduced by obtaining electrons provided by oxidation of the electrolyte 260. The oxidized electrolyte 260 may be re-reduced by electrons transmitted from an external circuit through the second grid electrode 223 and the second conductive film 222.

For example, the second conductive film 222 may include a transparent conductive film 222a and a catalyst layer 222b. The transparent conductive film 222a may be formed of a transparent and conductive material, and the catalyst layer 222b may be formed of a material that functions as a reducing catalyst that may provide electrons to the electrolyte 260.

In the current embodiment, the second conductive film 222 includes the transparent conductive film 222a and the catalyst layer 222b, but according to another embodiment, the second conductive film 222 may include one of the transparent conductive film 222a and the catalyst layer 222b.

According to at least one of the disclosed embodiments, a cell gap of a photoelectric conversion module between conductive substrates facing each other is reduced. Therefore, the ion mobility of an electrolyte is increased and the resistance of a light current pass is reduced, thereby increasing the efficiency of photoelectric conversion of the photoelectric conversion module.

It should be understood that the embodiments described therein should be considered in a descriptive sense only and not for purposes of limitation. Descriptions of features or aspects within each embodiment should typically be considered as available for other similar features or aspects in other embodiments.

What is claimed is:

1. A photoelectric conversion module comprising:
first and second conductive substrates facing each other;
first and second grid electrodes formed between and respectively electrically connected to the first and second conductive substrates; and
a first isolation electrode interposed between and contacting the first conductive substrate and the second grid electrode.

2. The photoelectric conversion module of claim 1, wherein the first conductive substrate comprises a first substrate and a first conductive film formed on the first substrate to be closer to the second conductive substrate than the first substrate.

3. The photoelectric conversion module of claim 2, wherein the first isolation electrode is electrically insulated from the first conductive film via an insulating gap formed therebetween.

4. The photoelectric conversion module of claim 3, wherein the insulating gap is formed as a line pattern along a surrounding of the second grid electrode.

5. The photoelectric conversion module of claim 2, wherein the first isolation electrode is physically separated from the first conductive film.

6. The photoelectric conversion module of claim 2, wherein the first isolation electrode is formed on the same level as the first conductive film on the first substrate.

7. The photoelectric conversion module of claim 2, wherein the first isolation electrode and the first conductive film are formed of the same material.

8. The photoelectric conversion module of claim 1, further comprising a protective layer formed along a lateral circumference of the second grid electrode.

9. The photoelectric conversion module of claim 8, wherein the protective layer is not formed on a surface of the second grid electrode that faces the first conductive substrate.

10. The photoelectric conversion module of claim 1, further comprising an electrolyte provided between the first and second conductive substrates, wherein the second grid electrode has a top surface that tightly contacts the first isolation electrode such that the electrolyte does not permeate or is substantially prevented from permeating between the top surface of the second grid electrode and the first isolation electrode.

11. The photoelectric conversion module of claim 1, further comprising:
an electrolyte provided between the first and second conductive substrates; and
a second isolation electrode interposed between and contacting the second conductive substrate and the first grid electrode,
wherein the first grid electrode has a bottom surface that tightly contacts the second isolation electrode such that the electrolyte does not permeate or is substantially prevented from permeating between the bottom surface of the first grid electrode and the second isolation electrode.

12. The photoelectric conversion module of claim 11, wherein the second conductive substrate comprises a second substrate and a second conductive film formed on the second substrate, and wherein the second isolation electrode is formed on the same level as the second conductive film on the second substrate.

13. The photoelectric conversion module of claim 1, further comprising a light absorption layer disposed between the first and second grid electrodes.

14. A photoelectric conversion module comprising:
first and second conductive substrates facing each other; and
first and second grid electrodes between and respectively electrically connected to the first and second conductive substrates,
wherein the first conductive substrate tightly contacts the second grid electrode.

15. The photoelectric conversion module of claim 14, wherein the first conductive substrate comprises a first substrate and a first conductive film formed on a first portion of the first substrate to be closer to the second conductive substrate than the first substrate, wherein the first substrate comprises a second portion where the first conductive film is not formed, and wherein the second grid electrode tightly contacts the second portion of the first substrate.

16. The photoelectric conversion module of claim 14, further comprising a protective layer formed along a lateral circumference of the second grid electrode.

17. The photoelectric conversion module of claim 16, wherein the protective layer is not formed on a surface of the second grid electrode that faces the first conductive substrate.

18. The photoelectric conversion module of claim 14, wherein the second conductive substrate tightly contacts the first grid electrode.

19. The photoelectric conversion module of claim 18, wherein the second conductive substrate comprises a second substrate and a second conductive film formed on a first portion of the second substrate to be closer to the first conductive substrate than the second substrate, wherein the second substrate comprises a second portion where the second conductive film is not formed, and wherein the first grid electrode tightly contacts the second portion of the second substrate.

20. A photoelectric conversion module comprising:
first and second conductive substrates facing each other;
first and second grid electrodes formed between and respectively electrically connected to the first and second conductive substrates; and
a first isolation electrode interposed between the first conductive substrate and the second grid electrode,
wherein the second grid electrode has a top surface that tightly contacts the first isolation electrode so as to substantially prevent an electrolyte from permeating between the top surface of the second grid electrode and the first isolation electrode.
